(19) United States
(12) Patent Application Publication
(10) Pub. No.: US 2025/0240926 A1
(43) Pub. Date: Jul. 24, 2025

(54) SPEAKER-INDUCED AIRFLOW FOR ACTIVE DEVICE COOLING

(71) Applicant: RealWear, Inc., Vancouver, WA (US)

(72) Inventors: Noah Nicholas BALMER, Vancouver, WA (US); Chris Iain Parkinson, Richland, WA (US); George Henry Hines, Petaluma, CA (US)

(21) Appl. No.: 18/416,278

(22) Filed: Jan. 18, 2024

(51) Int. Cl. H05K 7/20; H04R 1/02; H04R 9/02

(52) U.S. Cl. CPC H05K 7/20409; H04R 1/028; H04R 9/022; H05K 7/20136; H04R 2499/11

(57) ABSTRACT

A speaker-induced cooling system for a device aids in removing heat produced by a circuit system. A speaker box forms a speaker box opening having a speaker within it. A thermally conductive sheet extends contiguously from a first speaker box side around to a second speaker box side. Heat is transferred from the circuit system to the thermally conductive sheet at the first speaker box side and away from the device using a heat sink, which draws heat from a thermally conductive sheet at the second speaker box side. The heat sink includes sound openings between fins and is further cooled using air movement, created by the speaker, through the sound openings. The thermally conductive sheet further transfers heat into an enclosure of the speaker box. The heat is dissipated by a cool zone created by the speaker during use, which cools the overall device.

### BACKGROUND

Heat generation in electronic circuit systems is an inevitable byproduct of electrical energy conversion and resistance within the components. When electrical current flows through a circuit, some energy is lost, primarily as heat, due to the resistance offered by the components and conductive materials. In practical terms, devices like processors, power transistors, and other high-power components in a circuit are particularly prone to heat generation. Excessive heat can lead to reduced efficiency and malfunction of the electronic components.

To reduce heat from electrical components, many devices include heat sinks. A heat sink is a passive heat exchanger that absorbs and dissipates heat from hot components, thereby helping to maintain them within operating temperature limits. This process is aided by natural convection or forced airflow (such as from a fan), which carries the heat away from the heat sink. Heat sinks are used in a variety of applications, from computer CPUs (central processing units) and GPUs (graphics processing units) to power amplifiers and LED (light-emitting diode) lights, to control the temperature of electronic circuit systems.

### SUMMARY

At a high level, aspects of the present technology generally relate to speaker-induced heat dissipation from a device. In particular, a speaker system can be used to remove heat generated by a circuit system of a device, thereby helping to prevent damage to the device and increase the device's operational efficiency.

One example device uses a speaker box having a speaker that produces sound, including audible sound, which may be used as an audio output component of the device. The speaker box is curved at one end, and a thermally conductive sheet is wrapped around the speaker box from a first speaker box side to an opposite second speaker box side.

Heat from a circuit system of the device is transferred to the thermally conductive sheet at the first speaker box side. The heat can be drawn from the thermally conductive sheet using a heat sink at the second speaker box side.

In aspects, the thermally conductive sheet extends contiguously across a portion of the first speaker box side and the second speaker box side. Some of the heat generated by the circuit system is transferred into the speaker box, warming the air within the enclosure. This, in turn, warms the speaker, which is partially within the enclosure. Air movement caused by activation of the speaker's diaphragm during sound generation aids in heat dissipation from the enclosure to the external environment, further helping to cool the device.

This summary is intended to introduce a selection of concepts in a simplified form that is further described in this disclosure. The summary is not intended to identify key or essential features of the claimed subject matter, nor is it intended to be an aid in determining the scope of the claimed subject matter. Additional objects, advantages, and novel features of the technology will be set forth in part in the description that follows, and in part will become apparent to those skilled in the art upon examination of the disclosure or learned through practice of the technology.

### BRIEF DESCRIPTION OF THE DRAWINGS

The present technology is described in detail below with reference to the attached drawing figures, wherein:

FIG. 1 illustrates an example electronic device in which aspects of the technology are employed, in accordance with an aspect described herein;

FIG. 2 illustrates a bottom perspective view of an isolated device of FIG. 1, in accordance with an aspect described herein;

FIG. 3 illustrates an exploded view of the device of FIG. 2 in which components for generating speaker-induced airflow can be seen, in accordance with an aspect described herein; and

FIG. 4 illustrates a cross-sectional view of the device of FIG. 2 in which components for generating speaker-induced airflow can be seen, in accordance with an aspect described herein.

### DETAILED DESCRIPTION

Electronic devices, ranging from smartphones to laptops, are equipped with circuit systems that generate heat as a byproduct of their operation. This heat production is an inherent aspect of electronic function, as electrical energy, while passing through the components, encounters resistance and consequently releases energy in the form of heat. Managing this heat is part of device design, as excessive heat can impair functionality and reduce the efficiency of components. As electronic devices have become more compact and their computing power has increased, the challenge of effectively cooling the devices has grown.

In the field of small devices, such as wearables, smartphones, and compact computing devices, the constraints on space limit the options for heat management. Traditional cooling methods, like large heat sinks and fans, may be impractical due to size restrictions. Some methods for controlling heat from electrical circuit systems of small devices where traditional techniques are not as effective might include using materials with high thermal conductivity and designing efficient internal layouts that promote heat dispersion.

The challenge of cooling circuit systems in small devices is further compounded by the increasing power and functionality demanded of modern electronics. More powerful processors and denser circuit systems generate more heat, yet the limited space inhibits the ability to use larger, more efficient cooling mechanisms. Additionally, the need to balance heat management with other design considerations, such as battery life, weight, and aesthetics, adds layers of complexity to the design process.

The technology described herein generally relates to using a speaker of a device to generate airflow that helps dissipate heat emitted from the device's circuit system. In general, a speaker is an electromechanical device designed to convert electrical signals into audible sound. At its core, a typical speaker may comprise various components, such as a diaphragm (also known as a cone), a voice coil, and a magnet, along with other common or specialty components. In general, the diaphragm of a speaker might be a thin, flexible material that vibrates to produce sound waves. The vibration of the diaphragm compresses and rarefies the air in front of it, creating sound waves that can be heard as music or speech. The present technology provides a system that takes advantage of the air movement naturally created by a speaker during use to aid in dissipating heat generated by the circuit system of the device.

In the context of small electronic devices and wearables, such as the examples that will be described, taking advantage of the speaker's naturally created air movement provides a way to maximize the efficiency of the overall system in the sense that parts are used for more than one purpose, thus allowing smaller devices to include more powerful and efficient circuit systems and components. This approach maximizes limited space, allowing for more compact and lightweight designs. It not only reduces the device's size and weight, but also enhances performance and functionality.

An example speaker-induced cooling system that can be deployed in various devices, including wearable cameras, includes a speaker box. The speaker box forms an enclosure, which aids in enhancing the sound emitted by a speaker within the speaker box. The speaker box has a first speaker box side that is opposite a second speaker box side. The speaker box sides have interior surfaces that are within the enclosure, and which are opposite exterior surfaces outside of the enclosure.

A thermally conductive sheet extends across at least a portion of the exterior surface of the first speaker box side. The thermally conductive sheet wraps around a curved end of the speaker box, and then extends contiguously across at least a portion of the second speaker box side.

A heat sink is positioned so that the thermally conductive sheet at the second speaker box side is between the heat sink and the second speaker box side. In this way, heat produced by a circuit system can be transferred from the first speaker box side to the second speaker box side away from the thermally conductive sheet via the heat sink, thereby cooling the device, such as a camera, using the cooling system.

To further aid in cooling, the second speaker box side may form a speaker box opening in which a speaker is positioned. The speaker may be positioned so that part of it is within the enclosure. A sound opening may be formed from and extend through the heat sink at the speaker box opening, and it may be positioned between fins of the heat sink.

As such, when the speaker is in use, the speaker creates air movement inward and outward from the sound opening. This moving air helps to pull heat from the heat sink. Further, the design of the thermally conductive sheet around the speaker box also helps to draw heat from the components to the air within the enclosure. This heat is transferred to the speaker that is at least partially positioned within the enclosure. The movement of the diaphragm during use may generate a cool zone relative to the warmed air within the enclosure, thereby causing heat to transfer away from the enclosure via the speaker. The heat may then be drawn away by the airflow created from the diaphragm, which further aids in cooling the device.

It will be realized that the systems previously described are only examples that can be practiced from the description that follows, and it is provided to more easily understand the technology and recognize its benefits. Additional examples are now described with reference to the figures.

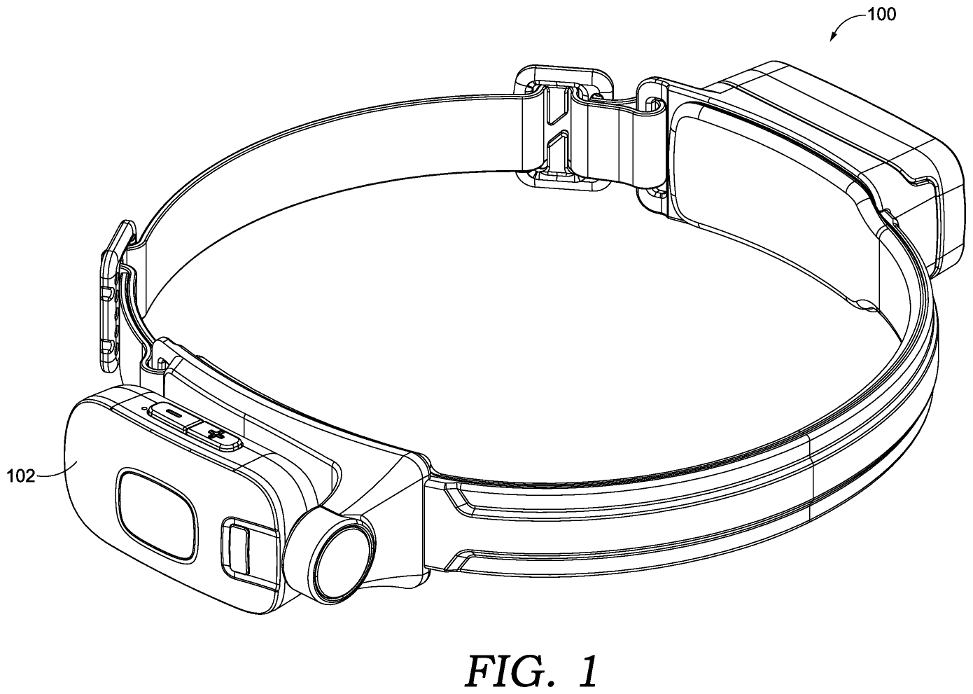

Turning first to FIG. 1, an example device in which aspects of the speaker-induced airflow system may be employed is illustrated. In FIG. 1, an example for describing the technology is provided and is generally illustrated as head-mounted camera system 100 having device 102. Device 102 is a device comprising an electrical circuit system for operationally controlling components of device 102, which may be cooled using speaker-induced airflow. In the example device 102 that is illustrated and will be further described, the device 102 may comprise a speaker suitable to generate audible sound. While device 102 is generally illustrated as a camera of head-mounted camera system 100, device 102 is generally illustrative of any device having electronic circuitry.

It is emphasized that head-mounted camera system 100 with device 102 of FIG. 1 is only one example, and that it would be impracticable to describe all the various different devices in which the speaker-induced airflow technology may be integrated. As such, head-mounted camera system 100 is only intended as illustrative. The system and methods for cooling a circuit system using speaker-induced airflow may be implemented in a variety of different devices with varying functionality. Devices in which the technology may be used include camera systems, such as the head-mounted camera systems described, security cameras, other body-worn cameras, general digital cameras and video systems, thermal cameras, microscopes cameras, child monitoring systems, and the like; smartphones and other cellular or satellite communication devices; portable speakers, such as portable Bluetooth speakers; headphones, earbuds, and the like; media players, such as MP3 players or video players; general computers, such as laptops, notebooks, and tablets; gaming devices, such as standalone or handled gaming devices; input devices, such as a computer mouse or videogame controller; or other like devices with electronic circuit systems in which a speaker may be employed.

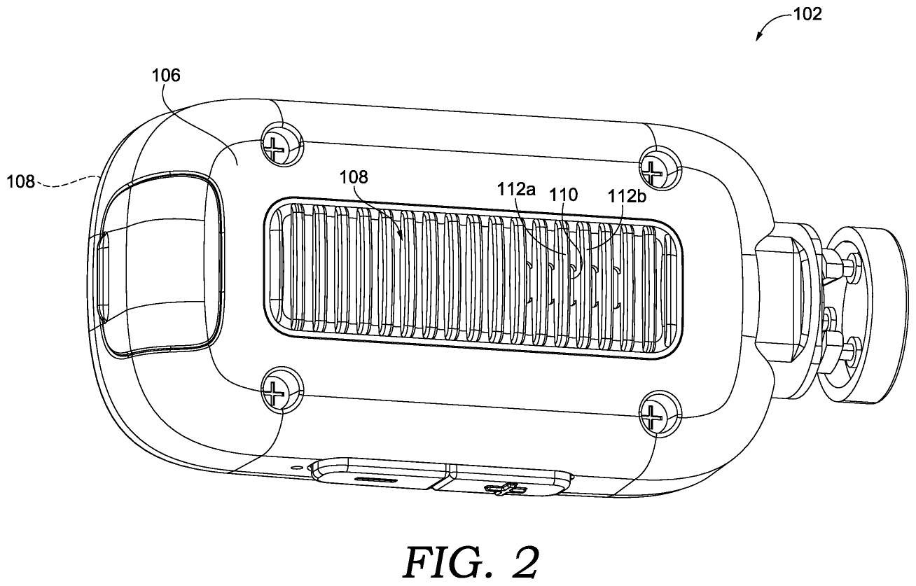

FIG. 2 illustrates device 102 as isolated from other components illustrated in FIG. 1. FIG. 2 illustrates a bottom perspective view of device 102. In the example illustrated, device 102 comprises first side 104 that is opposite second side 106. Heat sink 108, which aids in cooling device 102 in coordination with a speaker system, is provided at second side 106. Sound opening 110 is formed at least partially by heat sink 108 and is between first fin 112a and second fin 112b. As will be further described, the air movement caused by the speaker system helps draw heat away from heat sink 108, helping to cool device 102.

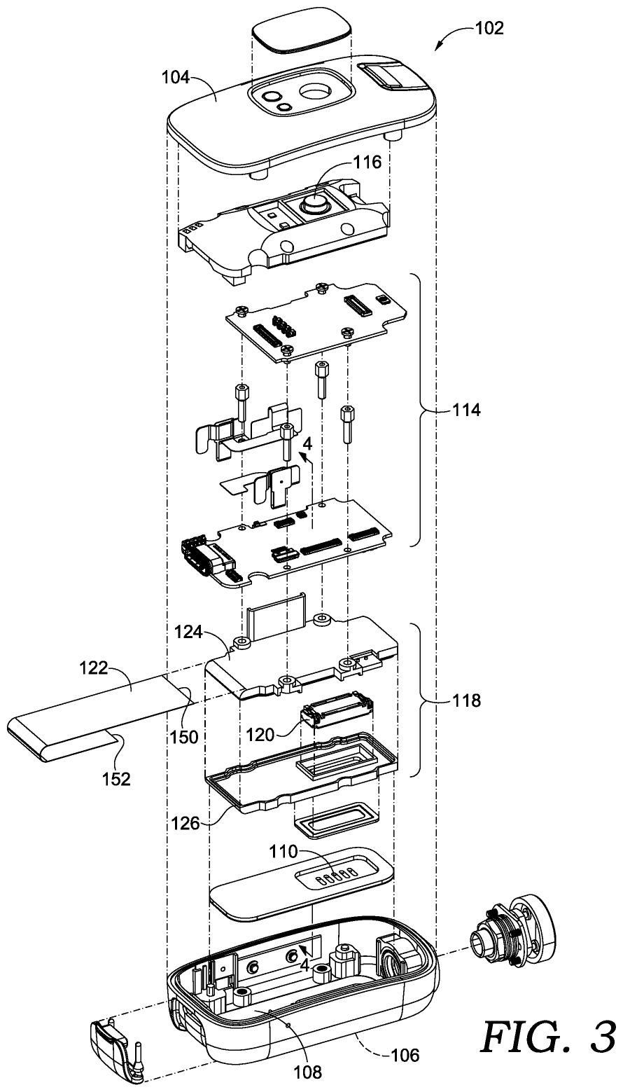

FIG. 3 offers an exploded view of the example device 102. Here, an example circuit system 114 that is operable to provide functionality to device 102 is illustrated. In general, circuit system 114 is intended to broadly include a network of interconnected electronic components that perform various functions within device 102. Circuit system 114 may be made up of various components like transistors, resistors, capacitors, inductors, diodes, and integrated circuits (ICs). Each component has a specific role, such as amplifying signals, storing energy, filtering frequencies, or controlling current flow. In many cases, the arrangement of these components determines the function of the circuit, and ultimately the device. This might range from simple tasks like lighting an LED to complex operations such as processing data or signals. In some cases, circuit system 114 comprises components mounted on one or more printed circuit boards (PCBs). These boards provide a physical base for the components and use conductive tracks, pads, and other features to electrically connect the components. In some cases, circuit system 114 may include interfaces for input and output, like connectors, switches, and display drivers, allowing device 102 to interact with users and other devices.

In a specific aspect, device 102 is a camera, which can include a head-mounted camera system. In such cases, circuit system 114 is communicatively coupled to an image sensor, e.g., charge-coupled device (CCD) or complementary metal oxide semiconductor (CMOS), that converts the optical image into an electrical signal. The image sensor may be positioned such that light-penetrating camera lens 116 is focused onto the image sensor.

In general, circuit system 114 generates heat when in use. This is primarily due to electrical resistance or inefficiencies in the electronic components, like the resistors, transistors, and ICs. Cooling often helps, especially in high-power or densely packed electronic devices, to prevent damage and achieve better performance.

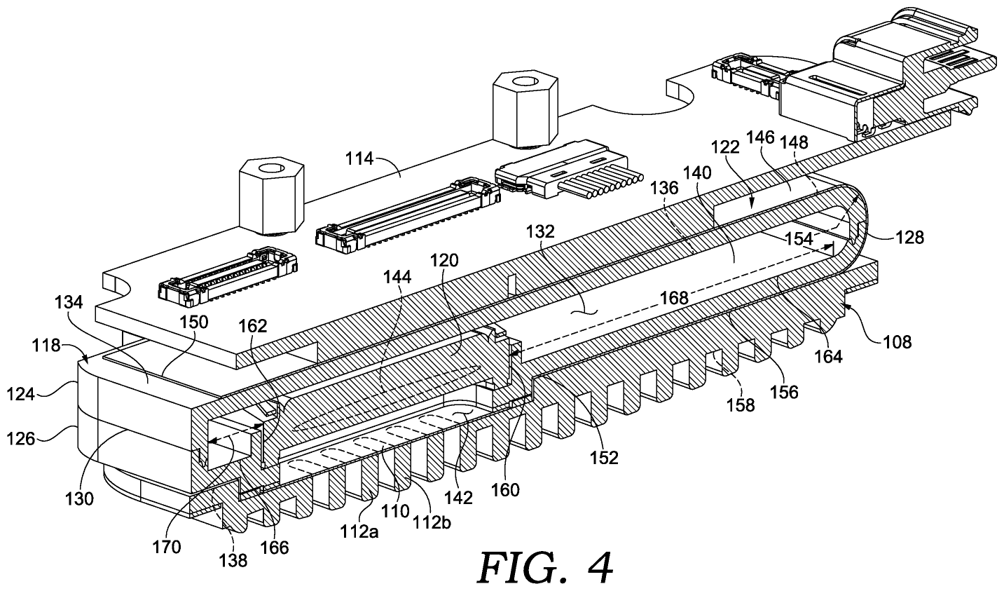

As will be further described, the cooling of device 102 is aided by a speaker system. At a high level, as illustrated in FIG. 3, the speaker system includes a speaker box 118 having speaker 120. Speaker box 118 is at least partially contiguous with thermally conductive sheet 122, which wraps around speaker box 118 to help move heat created by circuit system 114 from first speaker box side 124 to second speaker box side 126, where it can be removed via the heat sink 108. Aiding this, speaker 120 causes air movement through sound opening 110 when in use. It is noted that one or more components may form all or a portion of sound opening 110, and that in the particular example device 102 illustrated here, sound opening 110 is at least partially formed by heat sink 108, as will be further illustrated in FIG. 4. The air moved by speaker 120 through sound opening 110 is directed across the heat sink 108, helping cool heat sink 108 and cause a better transfer of heat from circuit system 114 to heat sink 108.

To further illustrate, FIG. 4 provides the cross-sectional view indicated in FIG. 3 and has select components of device 102 to help describe the speaker-induced cooling. Components of FIG. 4 may help remove heat generated by circuit system 114.

In the example illustrated, speaker box 118 comprises first speaker box side 124 opposite second speaker box side 126. First speaker box side 124 and second speaker box side 126 may be formed separately or may be a single integrated piece. That is, first speaker box side 124 and second speaker box side 126 may be separable, permanently coupled, or monolithic. Speaker box 118 further comprises first speaker box end 128 that is opposite second speaker box end 130.

Speaker box 118 at least partially forms enclosure 132, which comprises a chamber of air. Together with other components, speaker box 118 may form enclosure 132 in such a manner that enclosure 132 is a sealed chamber that allows little to no air movement in or out of enclosure 132. In another aspect, enclosure 132 is formed such that it is an open chamber, allowing some air to move in and out of enclosure 132. In general, enclosure 132 of speaker box 118 may enhance sound emitted by speaker 120.

Speaker box 118 comprises interior surfaces that are within enclosure 132 and exterior surfaces that are external relative to enclosure 132. As shown, first speaker box side 124 comprises first exterior surface 134 that extends between first speaker box end 128 and second speaker box end 130. In the aspect illustrated, first exterior surface 134 extends uninterrupted from first speaker box end 128 to second speaker box end 130. First speaker box side 124 further comprises first interior surface 136 within enclosure 132 that extends between first speaker box end 128 and second speaker box end 130. In the aspect illustrated, first interior surface 136 extends uninterrupted from first speaker box end 128 to second speaker box end 130.

Further, second speaker box side 126 comprises second exterior surface 138 that extends between first speaker box end 128 and second speaker box end 130. Second speaker box side 126 further comprises second interior surface 140 within enclosure 132 that extends between first speaker box end 128 and second speaker box end 130.

In the aspect illustrated, speaker box opening 142 is formed at least in part by second speaker box side 126. The speaker box opening 142 may be formed by and extend through second speaker box side 126. By doing so, speaker 120 may be positioned within speaker box opening 142. For instance, diaphragm 144 of speaker 120 that is suitable for generating audible sound is positioned within speaker box opening 142 so that sound can be projected from the speaker 120 external to the device. In aspects, speaker 120 can be provided within speaker box opening 142 in a manner that seals enclosure 132 at speaker box opening 142.

To aid in cooling, thermally conductive sheet 122 may remove heat generated by circuit system 114 via heat sink 108. Thermally conductive sheet 122 may be formed from a thermally conductive material. For instance, thermally conductive sheet 122 may comprise carbon-based materials, such as graphite; metals, such as copper, silver, aluminum, and so forth; ceramics; and the like. Thermal conductivity may be measured using watts per meter per Kelvin (W/m·K). In an aspect, thermally conductive sheet 122 may be formed of a material having a thermal conductivity of 90 W/m· K or greater. Such materials are generally sufficient for heat transfer through the device. Thermally conductive sheet 122 comprises first thermally conductive sheet surface 146 opposite of second thermally conductive sheet surface 148.

To help transfer heat from circuit system 114 to heat sink 108, thermally conductive sheet 122 may extend between first speaker box end 128 and second speaker box end 130 along first exterior surface 134. Thermally conductive sheet 122 may continue and extend between first speaker box end 128 and second speaker box end 130 along second exterior surface 138. In doing so, the heat generated by circuit system 114 is transferred to thermally conductive sheet 122 at a location corresponding to first speaker box side 124 and moved along thermally conductive sheet 122 to a location corresponding to second speaker box side 126, where the portion of thermally conductive sheet 122 at second speaker box side 126 is nearer to heat sink 108, which draws the heat from thermally conductive sheet 122.

In aspects, thermally conductive sheet 122 extends from first sheet end 150 to second sheet end 152. In some cases, first sheet end 150 is positioned at first exterior surface 134 of speaker box 118. Second sheet end 152 may be positioned at second exterior surface 138 of speaker box 118. In doing so, thermally conductive sheet 122 may extend from first sheet end 150 at first speaker box side 124 to second sheet end 152 at second speaker box side 126.

In the example illustrated, first sheet end 150 is at a location of first speaker box side 124 that is nearer second speaker box end 130 relative to the location at which second sheet end 152 is positioned at second speaker box side 126. This may help increase the relative surface area of thermally conductive sheet 122 that extends along first speaker box side 124 and second speaker box side 126, while allowing room for speaker 120.

In the example illustrated, first thermally conductive sheet surface 146 is proximate circuit system 114 such that heat is transferred from circuit system 114 to thermally conductive sheet 122 at first thermally conductive sheet surface 146. In this aspect, thermally conductive sheet 122 is positioned at speaker box 118 such that first thermally conductive sheet surface 146 is also directly adjacent at least a portion of heat sink 108, such that heat is transferred from thermally conductive sheet 122 to heat sink 108 at first thermally conductive sheet surface 146. A portion of thermally conductive sheet 122 may be disposed between first speaker box side 124 of speaker box 118 and circuit system 114 to aid in heat transfer away from circuit system 114. A portion of thermally conductive sheet 122 may be disposed between first heat sink side 156 of heat sink 108 and second exterior surface 138 of second speaker box side 126 of speaker box 118, which aids in drawing heat away from thermally conductive sheet 122 to be dissipated by heat sink 108.

In an aspect, thermally conductive sheet 122 extends from first speaker box side 124 to second speaker box side 126 about first speaker box end 128. For instance, thermally conductive sheet 122 may extend about first speaker box end 128 such that thermally conductive sheet 122 is contiguous with first speaker box end 128. In an aspect, thermally conductive sheet 122 extends about first speaker box end 128 only, and does not extend about second speaker box end 130, which aids in increasing heat transfer between circuit system 114 and heat sink 108, while reducing the width of the system and still allowing room for speaker 120, thereby allowing for more compact use of the system, along with increased ease of assembly when placing thermally conductive sheet 122 contiguous with speaker box 118.

In aspects, first speaker box end 128 is curved. For instance, first speaker box end 128 may be curved about radius 154, as measured from first speaker box side 124 and second speaker box side 126, forming a curved exterior surface. In aspects, radius 154 measures 10 millimeters (mm) or less, 8 mm or less, 6 mm or less, 4 mm or less, 2 mm or less, 1 mm or less, or any length as dictated by a device or components thereof.

In aspects where first speaker box end 128 is curved, thermally conductive sheet 122 may contiguously extend about the curved exterior surface, such that thermally conductive sheet 122 extends from first speaker box side 124 to second speaker box side 126. That is, thermally conductive sheet 122 may contiguously extend about the curved exterior surface of first speaker box end 128 from first exterior surface 134 to second exterior surface 138 of the speaker box 118.

Thermally conductive sheet 122 may be contiguous with at least a portion of first exterior surface 134 and second exterior surface 138 of speaker box 118. Thermally conductive sheet 122 comprises first thermally conductive sheet surface 146 opposite second thermally conductive sheet surface 148. A portion of second thermally conductive sheet surface 148 may be contiguous with first speaker box side 124, while a portion of second thermally conductive sheet surface 148 is also contiguous with second speaker box side 126. This configuration can help aid heat transfer into an enclosure so that heat can be dissipated by speaker 120.

Aspects of the technology may also use speaker 120 dissipated from circuit system 114 via enclosure 132. To aid in heat transfer out of enclosure 132 by speaker 120, speaker 120 may be positioned at least partially within enclosure 132 at speaker box opening 142. In aspects, speaker 120 and speaker box opening 142 are positioned at second speaker box side 126 in a manner that increases the relative contact area between thermally conductive sheet 122 and speaker box 118. In the example illustrated, speaker 120 comprises first speaker end 160 opposite of second speaker end 162.

When speaker 120 is in speaker box opening 142, first speaker end 160 may correspond to a first end of speaker box opening 142, while second speaker end 162 corresponds to a second end of speaker box opening 142. In the example, second speaker box side 126 comprises first portion 164 that extends between first speaker end 160, e.g., the first end of speaker box opening 142, and first speaker box end 128, while second portion 166 of second speaker box side 126 extends between second speaker end 162, e.g., the second end of speaker box opening 142, and second speaker box end 130.

To position speaker 120 to increase the relative contact between thermally conductive sheet 122 and speaker box 118 to improve heat transfer, length 168 of first portion 164, as measured from first speaker end 160 to first speaker box end 128, may be longer than length 170 of second portion 166, as measured from second speaker end 162 to second speaker box end 130. As such, first portion 164 of second speaker box side 126 may be disposed between at least a portion of thermally conductive sheet 122 contiguous with the first speaker box side 124 and at least a portion of thermally conductive sheet 122 contiguous with the second speaker box side 126.

As noted, device 102 further comprises heat sink 108. Heat sink 108 has a first heat sink side 156 opposite second heat sink side 158. One or more fins extend away from second heat sink side 158, increasing the surface area of heat sink 108 that is used for dissipating heat.

In aspects, heat sink 108 at least partially defines one or more sound openings. The one or more sound openings may be at least partially formed through the heat sink 108. For instance, a sound opening may be at least partially formed through heat sink 108 from first heat sink side 156 to second heat sink side 158. The one or more sound openings may be positioned at speaker box opening 142, which aids sound emission from speaker 120. In aspects, sound openings may comprise a mesh, where the mesh is sized to prevent water and debris from entering the speaker opening, while also allowing sound to be emitted from the sound openings.

In an aspect, heat sink 108 comprises sound opening 110, which is between first fin 112a and second fin 112b. When diaphragm 144 produces sound, it moves air, some of which is pushed in and out of sound opening 110. This provides additional air movement across first fin 112a and second fin 112b, which further helps to cool device 102.

Embodiments described above may be combined with one or more of the specifically described alternatives. In particular, an embodiment that is claimed may contain a reference, in the alternative, to more than one other embodiment. The embodiment that is claimed may specify a further limitation of the subject matter claimed.

The subject matter of the present technology is described with specificity herein to meet statutory requirements. However, the description itself is not intended to limit the scope of this disclosure. Rather, the inventors have contemplated that the claimed or disclosed subject matter might also be embodied in other ways, to include different steps or combinations of steps similar to the ones described in this document, in conjunction with other present or future technologies. Moreover, although the terms “step” or “block” might be used herein to connote different elements of methods employed, the terms should not be interpreted as implying any particular order among or between various steps herein disclosed unless and except when the order of individual steps is explicitly stated.

For purposes of this disclosure, the word “including,” “having,” and other like words and their derivatives have the same broad meaning as the word “comprising.”

The use of “extending between” is meant to convey a general direction or structure of object. Thus, an object may “extend between” two ends without extending fully from one end to the other. Put another way, an object may “extend between” two ends where the object measures only part of the distance relative to a full distance measured from one end to the other end. The term “extends between” and like derivatives are intended to include objects extending both partly end-to-end and fully end-to-end from one end to the other end.

As used throughout, “contiguous” generally means in direct contact for at least a portion of two components. For example, if a is contiguous with b, at least a portion of a contacts b at some location. It will be understood that bonding agents, including physical or chemical bonding agents, could be used to bond contiguous components. As such, a may still be contiguous with b, even when bonding agents are in place between a and b.

Words such as “a” and “an,” unless otherwise indicated to the contrary, include the plural as well as the singular. Thus, for example, the constraint of “a feature” is satisfied where one or more features are present. Also, the term “or” includes the conjunctive, the disjunctive, and both (a or b thus includes either a or b, as well as a and b).

From the foregoing, it will be seen that this technology is one well-adapted to attain all the ends and objects described above, including other advantages that are obvious or inherent to the structure. It will be understood that certain features and subcombinations are of utility and may be employed without reference to other features and subcombinations. This is contemplated by and is within the scope of the claims. Since many possible embodiments of the described technology may be made without departing from the scope, it is to be understood that all matter described herein or illustrated by the accompanying drawings is to be interpreted as illustrative and not in a limiting sense.

1-20. (canceled)

21. A speaker-induced cooling system for a device, the system comprising:
a speaker box forming an enclosure, the speaker box having a first speaker box side opposite a second speaker box side, the first speaker box side having a first exterior surface opposite a first interior surface within the enclosure and the second speaker box side having a second exterior surface opposite a second interior surface within the enclosure;
a thermally conductive sheet contiguous with at least a portion of the first exterior surface and the second exterior surface of the speaker box; and
a speaker box opening formed at least in part by the second speaker box side.

22. The speaker-induced cooling system of claim 21, wherein the speaker box further comprises a first speaker box end opposite a second speaker box end, the first speaker box end having a curve, the thermally conductive sheet contiguously extending about a curved exterior surface of the first speaker box end from the first exterior surface to the second exterior surface of the speaker box.

23. The speaker-induced cooling system of claim 21, wherein the thermally conductive sheet extends between a first sheet end and a second sheet end, the first sheet end positioned at the first exterior surface of the speaker box and the second sheet end positioned at the second exterior surface of the speaker box.

24. The speaker-induced cooling system of claim 23, wherein the first sheet end is nearer to the second speaker box end than the second sheet end.

25. The speaker-induced cooling system of claim 23, wherein:
the speaker box opening comprises a first speaker box opening end and a second speaker box opening end, the first speaker box opening end being nearer the first speaker box end than the second speaker box opening end, and the second speaker box opening end being nearer the second speaker box end than the first speaker box opening end; and
the second sheet end of the thermally conductive sheet is adjacent the first speaker box opening end.

26. The speaker-induced cooling system of claim 21, further comprising a speaker within the speaker box opening formed by the second speaker box side, wherein a portion of the speaker is disposed within the enclosure formed by the speaker box.

27. The speaker-induced cooling system of claim 26, wherein:
the speaker has a first speaker end opposite a second speaker end;
the second speaker box side comprises a first portion and a second portion, the first portion extending between the first speaker end and the first speaker box end, and the second portion extending between the second speaker end and the second speaker box end; and
the first portion of the second speaker box side is disposed between at least a portion of the thermally conductive sheet contiguous with the first speaker box side and at least a portion of the thermally conductive sheet contiguous with the second speaker box side.

28. A device employing a speaker-induced cooling system, the device comprising:
a speaker box forming an enclosure, the speaker box having a first speaker box side opposite a second speaker box side, the first speaker box side having a first exterior surface opposite a first interior surface within the enclosure and the second speaker box side having a second exterior surface opposite a second interior surface within the enclosure;
a thermally conductive sheet contiguous with at least a portion of the first exterior surface and the second exterior surface of the speaker box;
a circuit system, wherein a portion of the thermally conductive sheet is disposed between the circuit system and the first exterior surface of the speaker box; and
a speaker box opening formed at least in part by the second speaker box side.

29. The device of claim 28, wherein the speaker box further comprises a first speaker box end opposite a second speaker box end, the first speaker box end having a curve, the thermally conductive sheet contiguously extending about a curved exterior surface of the first speaker box end from the first exterior surface to the second exterior surface of the speaker box.

30. The device of claim 28, wherein the thermally conductive sheet extends between a first sheet end and a second sheet end, the first sheet end positioned at the first exterior surface of the speaker box and the second sheet end positioned at the second exterior surface of the speaker box.

31. The device of claim 30, wherein the first sheet end is nearer to the second speaker box end than the second sheet end.

32. The device of claim 30, wherein:
the speaker box opening comprises a first speaker box opening end and a second speaker box opening end, the first speaker box opening end being nearer the first speaker box end than the second speaker box opening end, and the second speaker box opening end being nearer the second speaker box end than the first speaker box opening end; and
the second sheet end of the thermally conductive sheet is adjacent the first speaker box opening end.

33. The device of claim 28, further comprising a speaker within the speaker box opening formed by the second speaker box side, wherein a portion of the speaker is disposed within the enclosure formed by the speaker box.

34. The device of claim 33, wherein:
the speaker has a first speaker end opposite a second speaker end;
the second speaker box side comprises a first portion and a second portion, the first portion extending between the first speaker end and the first speaker box end, and the second portion extending between the second speaker end and the second speaker box end; and
the first portion of the second speaker box side is disposed between at least a portion of the thermally conductive sheet contiguous with the first speaker box side and at least a portion of the thermally conductive sheet contiguous with the second speaker box side.

35. A camera employing a speaker-induced cooling system, the camera comprising:
a speaker box forming an enclosure, the speaker box having a first speaker box side opposite a second speaker box side, the first speaker box side having a first exterior surface opposite a first interior surface within the enclosure and the second speaker box side having a second exterior surface opposite a second interior surface within the enclosure;
a thermally conductive sheet contiguous with at least a portion of the first exterior surface and the second exterior surface of the speaker box;
a circuit system communicatively coupled to an image sensor, wherein a portion of the thermally conductive sheet is disposed between the circuit system and the first exterior surface of the speaker box; and
a speaker box opening formed at least in part by the second speaker box side.

36. The camera of claim 35, wherein the speaker box further comprises a first speaker box end opposite a second speaker box end, the first speaker box end having a curve, the thermally conductive sheet contiguously extending about a curved exterior surface of the first speaker box end from the first exterior surface to the second exterior surface of the speaker box.

37. The camera of claim 35, wherein the thermally conductive sheet extends between a first sheet end and a second sheet end, the first sheet end positioned at the first exterior surface of the speaker box and the second sheet end positioned at the second exterior surface of the speaker box.

38. The camera of claim 37, wherein the first sheet end is nearer to the second speaker box end than the second sheet end.

39. The camera of claim 37, wherein:
the speaker box opening comprises a first speaker box opening end and a second speaker box opening end, the first speaker box opening end being nearer the first speaker box end than the second speaker box opening end, and the second speaker box opening end being nearer the second speaker box end than the first speaker box opening end; and
the second sheet end of the thermally conductive sheet is adjacent the first speaker box opening end.

40. The camera of claim 35, further comprising a speaker within the speaker box opening formed by the second speaker box side, wherein a portion of the speaker is disposed within the enclosure formed by the speaker box.
